(19) United States
(12) Patent Application Publication
(10) Pub. No.: US 2017/0250755 A1
(43) Pub. Date: Aug. 31, 2017

(54) SEMICONDUCTOR DEVICE

(71) Applicant: Renesas Electronics Corporation, Tokyo (JP)

(72) Inventor: Seiji KAWATA, Tokyo (JP)

(21) Appl. No.: 15/432,899

(22) Filed: Feb. 14, 2017

(30) Foreign Application Priority Data
Feb. 29, 2016 (JP) 2016-037202
Nov. 9, 2016 (JP) 2016-218872

(51) Int. Cl. H04B 10/50; G02F 1/01; H01L 31/103; H04B 10/079; H01L 31/028; H01L 31/0304; H01S 5/00; H04B 10/54

(52) U.S. Cl. CPC H04B 10/50593; H01S 5/0085; G02F 1/011; H04B 10/541; H04B 10/0799; H01L 31/028; H01L 31/0304; H01L 31/103; H01L 31/1035; G02F 2201/58; G02F 2201/06

(57) ABSTRACT

A second optical modulator is provided between a semiconductor laser and a first optical modulator. Further, a second optical waveguide branched from a first optical waveguide is provided between the semiconductor laser and the second optical modulator, and a light receiving element which converts received laser light into a second electrical signal is provided at an end of the second optical waveguide. Furthermore, the second optical modulator adjusts a light intensity of the laser light entering the first optical modulator to a fixed light intensity, based on data transmitted as the second electrical signal. Still further, the first optical modulator modulates the laser light based on data transmitted as a first electrical signal, and converts the first electrical signal into an optical signal.

### CROSS-REFERENCE TO RELATED APPLICATION

The present application claims priority from Japanese Patent Applications No. 2016-037202 filed on Feb. 29, 2016 and No. 2016-218872 Nov. 9, 2016, the contents of which are hereby incorporated by reference into this application.

### TECHNICAL FIELD OF THE INVENTION

The present invention relates to a semiconductor device and can be suitably used for a semiconductor device including a built-in silicone photonics device, for example.

### BACKGROUND OF THE INVENTION

Japanese Patent Application Laid-Open No. 2012-226281 (Patent Document 1) discloses an optical transmitter which includes a semiconductor laser chip, an optical isolator and an optical fiber stub. A surface of this optical transmitter facing the semiconductor laser chip of a stem is provided with a monitor which receives backward output light emitted from a back side of the semiconductor laser chip.

### SUMMARY OF THE INVENTION

According to a silicone photonics technique, laser light emitted from a back surface of a semiconductor laser is received by a monitor element disposed at a back of the semiconductor laser, and feeds back this signal to monitor an oscillation state of the semiconductor laser. However, when the laser light is reflected by a reflection surface on an optical path, returning light fluctuates a light intensity of the laser light. There is a problem that: this fluctuation of the light intensity makes different behaviors at a front side and at a back side of the semiconductor laser; and therefore the monitor element disposed at the back of the semiconductor laser cannot control the light intensity of the laser light with high precision.

Other tasks and new features will become more apparent from the description of the present specification and the accompanying drawings.

A semiconductor device according to one embodiment includes: a semiconductor laser; a optical waveguide in which laser light emitted from the semiconductor laser propagates; a first optical modulator which modulates the laser light propagating in the optical waveguide, based on data transmitted as an electrical signal, and converts the electrical signal into an optical signal; and a second optical modulator which is disposed between the semiconductor laser and the first optical modulator and adjusts a light intensity of the laser light entering the first optical modulator.

Also, a semiconductor device according to one embodiment includes: a semiconductor laser; a semiconductor laser driver which drives the semiconductor laser; an optical waveguide in which laser light emitted from the semiconductor laser propagates; and an optical modulator which modulates the laser light propagating in the optical waveguide, based on first data transmitted as a first electrical signal, and converts the first electrical signal into an optical signal. Further, the semiconductor device includes a monitor element which is disposed between the semiconductor laser and the optical modulator and converts the received laser light into a second electrical signal. In addition, a light intensity of the laser light emitted from the semiconductor laser is adjusted by controlling the semiconductor laser driver based on second data transmitted as the second electrical signal.

According to one embodiment, it is possible to improve communication quality of a semiconductor device including a built-in silicone photonics device.

### BRIEF DESCRIPTIONS OF THE DRAWINGS

FIG. 1 is a schematic view illustrating an example of a configuration of a semiconductor device according to a first embodiment;

FIG. 2A is a plan view schematically illustrating a configuration of a light source according to the first embodiment;

FIG. 2B is a side view schematically illustrating a configuration of a light source according to the first embodiment;

FIG. 3A is a graphical representation schematically illustrating alight intensity of laser light in case where a second optical modulator does not manipulate a phase;

FIG. 3B is a graphical representation schematically illustrating a light intensity of laser light in case where the second optical modulator manipulates a phase;

FIG. 4 is a graphical representation schematically illustrating the light intensity of laser light before and after the second optical modulator manipulates the phase;

FIG. 5A is a plan view schematically illustrating a configuration of a light source according to a modified example of the first embodiment;

FIG. 5B is a side view schematically illustrating a configuration of a light source according to a modified example of the first embodiment;

FIG. 6A is a plan view schematically illustrating a configuration of a light source according to a second embodiment;

FIG. 6B is a side view schematically illustrating a configuration of a light source according to a second embodiment;

FIG. 7A is a plan view schematically illustrating a configuration of a light source according to a third embodiment;

FIG. 7B is a side view schematically illustrating a configuration of a light source according to a third embodiment;

FIG. 8A is a plan view schematically illustrating a configuration of a light source according to a fourth embodiment;

FIG. 8B is a side view schematically illustrating a configuration of a light source according to a fourth embodiment;

FIG. 9A is a plan view schematically illustrating a configuration of a light source according to a modified example of the fourth embodiment;

FIG. 9B is a side view schematically illustrating a configuration of a light source according to a modified example of the fourth embodiment;

FIG. 10A is a plan view schematically illustrating a configuration of a light source compared and studied by the inventors of the present invention; and

FIG. 10B is a side view schematically illustrating a configuration of a light source compared and studied by the inventors of the present invention.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable.

Further, in the embodiments described below, it goes without saying that the components (including element steps) are not always indispensable unless otherwise stated or except the case where the components are apparently indispensable in principle.

Also, even when mentioning that constituent elements or the like are “made of A” or “made up of A” in the embodiments below, elements other than A are of course not excluded except the case where it is particularly specified that A is the only element thereof. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Also, in some drawings used in the following embodiments, hatching is omitted even in a cross-sectional view so as to make the drawings easy to see. In addition, hatching is used even in a plan view so as to make the drawings easy to see.

In recent years, a technique of: making transmission lines by using silicone (Si) as a material; using an optical circuit configured by these transmission lines as a platform; and integrating various optical devices and electronic devices realize an optical communication module, i.e., a so-called silicone photonics technique is actively developed.

Technical contents disclosed in the present embodiment is a technique in particular applied to a light source configured by a semiconductor laser etc. among various devices configuring semiconductor devices which use the silicone photonics technique. Hereinafter, a light source and optical signal transmission lines (referred to as “optical waveguides” below) will be mainly described in the present embodiment.

(Detailed Description of Problem)

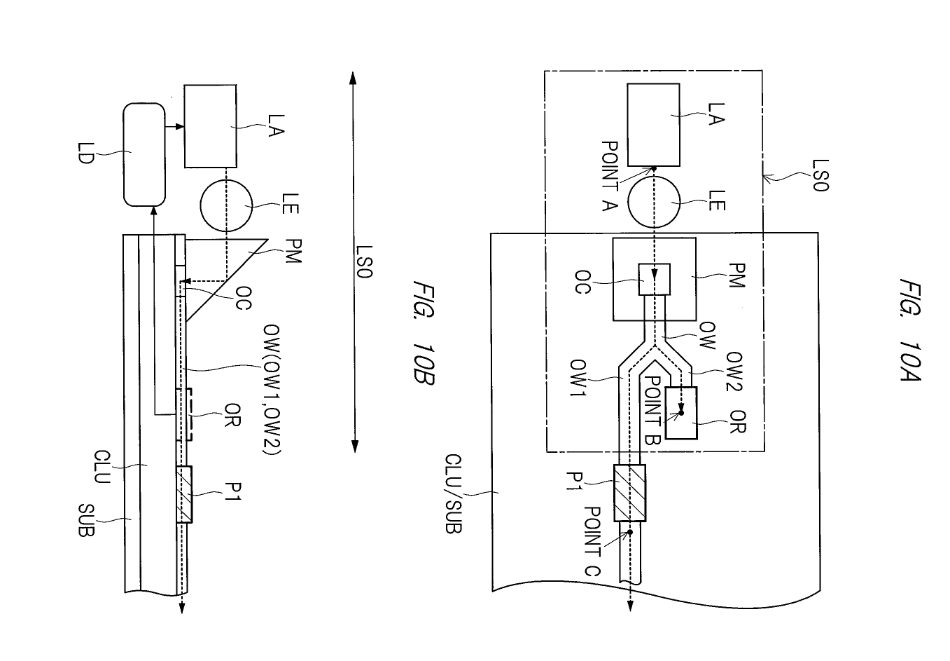

First, a configuration of a light source which the inventors of the present invention have studied so far will be described with reference to FIGS. 10A and 10B to clarify a configuration of a light source having a semiconductor laser according to the present embodiment. FIGS. 10A and 10B are a plan view and a side view schematically illustrating the configuration of the light source which the inventors of the present invention have compared and studied.

Normally, according to the silicone photonics technique, the monitor element disposed at the back of the semiconductor laser receives laser light emitted from the back surface of the semiconductor laser, and feeds back the signal of the laser light to monitor the oscillation state of the semiconductor laser (see Patent Document 1). However, when the laser light is reflected by the reflection surface on the optical path, the returning light fluctuates the light intensity of the laser light. This light intensity fluctuation makes different behaviors at the front side and the back side of the semiconductor laser, and therefore the monitor element disposed at the back of the semiconductor laser cannot control the light intensity of the laser light with high precision.

Hence, the inventors of the present invention have studied controlling the light intensity of the laser light by using part of beams of laser light emitted from a front surface of the semiconductor laser, i.e., by using part of beams of laser light propagating to optical waveguides.

As illustrated in FIGS. 10A and 10B, a light source LSO which the inventors of the present invention have compared and studied includes a semiconductor laser LA, a semiconductor laser driver LD, a lens LE, a prism mirror PM, an optical coupling element OC, an optical waveguide OW and a light receiving element OR.

The semiconductor laser LA is driven by the semiconductor laser driver LD and emits light. Laser light emitted from a front surface of the semiconductor laser LA enters the optical coupling element OC via the lens LE and the prism mirror PM, and then propagates in the optical waveguide OW.

The optical waveguide OW in which the laser light has entered is branched into two; a first optical waveguide OW1 as one of the two extends to an outside of the light source LSO; and a second optical waveguide OW2 as the other does not extend to the outside of the light source LSO and has an end provided with the light receiving element OR which receives part of beams of the laser light.

The laser light having entered the first optical waveguide OW1 enters a first optical modulator P1, and is modulated by the first optical modulator P1 according to an external electrical signal. The light receiving element OR receives the laser light having entered the second optical waveguide OW2, and monitors a fluctuation of a light intensity of the laser light. The light receiving element OR feeds back the monitored fluctuation of the light intensity of the laser light to the semiconductor laser driver LD to adjust the light intensity of the laser light emitted from the semiconductor laser LA.

However, according to the above method, the fluctuation of the light intensity of the laser light monitored by the light receiving element OR is used to correct a drive current of the semiconductor laser LA. Therefore, at a point in time (point A) at which the semiconductor laser LA emits the corrected laser light, the correction target laser light propagating in the first optical waveguide OW1 is at a position (point C) further than a point in time (point B) at which the light receiving element OR has already monitored the laser light.

Therefore, even when part of beams of the laser light emitted from the front surface of the semiconductor laser LA is used, it is difficult to precisely correct the light intensity of the laser light by adjusting the light intensity of the laser light through the light receiving element OR and the semiconductor laser driver LD.

### First Embodiment

<<Configuration of Semiconductor Device>>

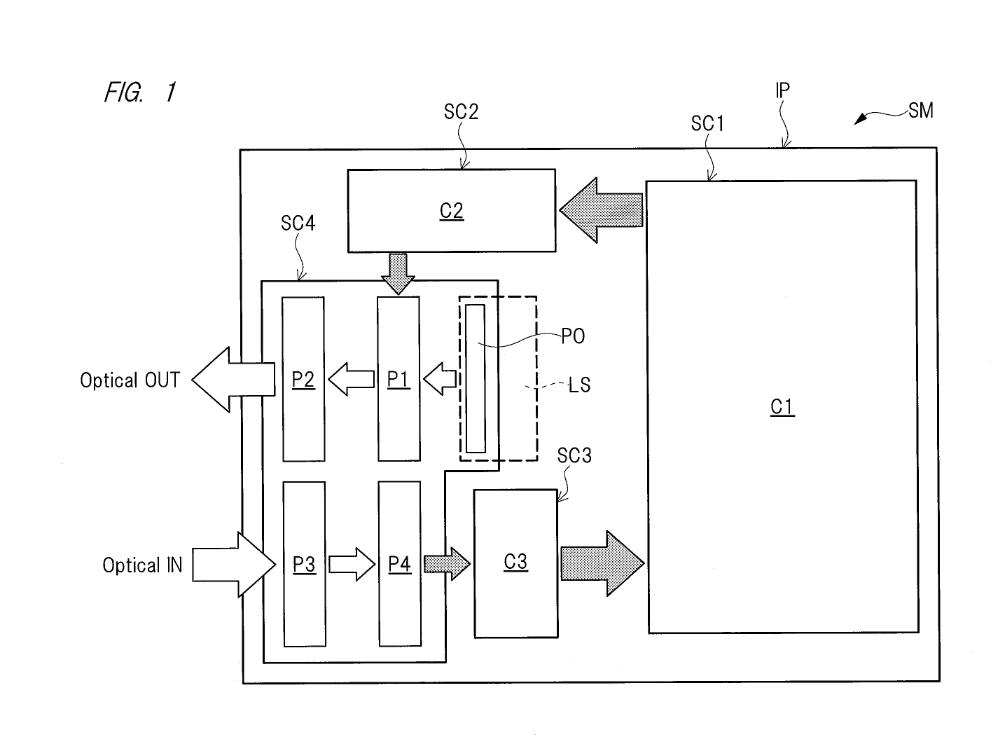

An example of a configuration of a semiconductor device according to a first embodiment will be described with reference to FIG. 1. FIG. 1 is a schematic view illustrating the example of the configuration of the semiconductor device according to the first embodiment.

As illustrated in FIG. 1, data outputted from a silicone electronic circuit C1 on which, for example, a control circuit or a memory circuit is formed is transmitted as an electrical signal to a first optical modulator P1 via a silicone electronic circuit (transceiver IC (Integrated Circuit)) C2. The first optical modulator P1 is an optical device which converts the data transmitted as the electrical signal into an optical signal. For example, continuous wave laser light enters the first optical modulator P1 from a light source LS. The first optical modulator P1 manipulates a phase of light and changes a state of the optical signal, so that it is possible to associate the data transmitted as the electrical signal with a light phase state. The light source LS is composed of, for example, a semiconductor laser, a lens, a prism mirror and an optical coupling element.

A semiconductor device SM outputs the optical signal modulated by the first optical modulator P1 to an outside via an optical coupler P2 such as a grating coupler or a spot size converter.

Meanwhile, the semiconductor device SM transmits the inputted optical signal to a light receiver P4 via an optical coupler P3 such as a grating coupler or a spot size converter. The light receiver P4 is an optical device which converts the data transmitted as the optical signal into an electrical signal. Further, the light receiver P4 transmits the data converted into the electrical signal to the silicone electronic circuit C1 via a silicone electronic circuit (receiver IC (Integrated Circuit)) C3.

The electrical signal transmitted from the silicone electronic circuit C1 to the first optical modulator P1 via the silicone electronic circuit C2, and the electronic signal transmitted from the light receiver P4 to the silicone electronic circuit C1 via the silicone electronic circuit C3 are transmitted by using electrical wires mainly made of a conductive material such as aluminum (Al), copper (Cu) or tungsten (W). Meanwhile, optical signals are transmitted by using optical signal transmission lines formed by, for example, a polycrystalline silicone film.

Further, the silicone electronic circuit C1, the silicone electronic circuit C2 and the silicone electronic circuit C3 are formed on semiconductor chips SC1, SC2 and SC3, respectively. Furthermore, the first optical modulator P1, the optical couplers P2 and P3 and the light receiver P4 are formed on one semiconductor chip SC4. Still further, part of members which compose the light source LS, such an optical coupling element PO, is also formed on the semiconductor chip SC4. These semiconductor chips SC1, SC2, SC3 and SC4 and the light source LS are mounted on, for example, one interposer IP to compose one semiconductor device SM.

In this regard, the electronic devices and the optical devices are formed on the different semiconductor chips, and the embodiment is not limited to these. For example, the electronic devices and the optical devices can also be formed on one semiconductor chip.

<<Configuration of Light Source>>

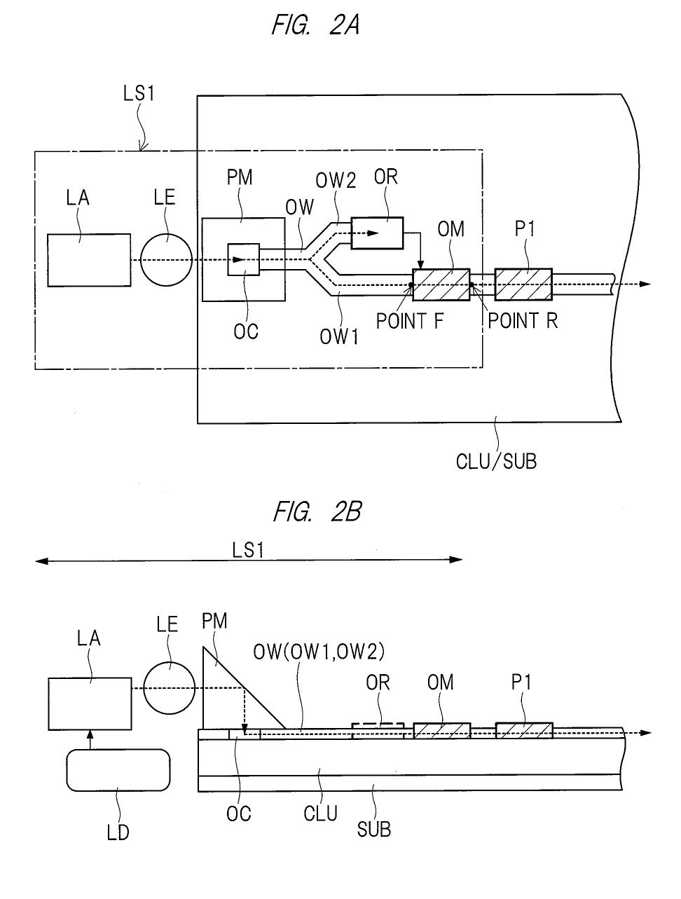

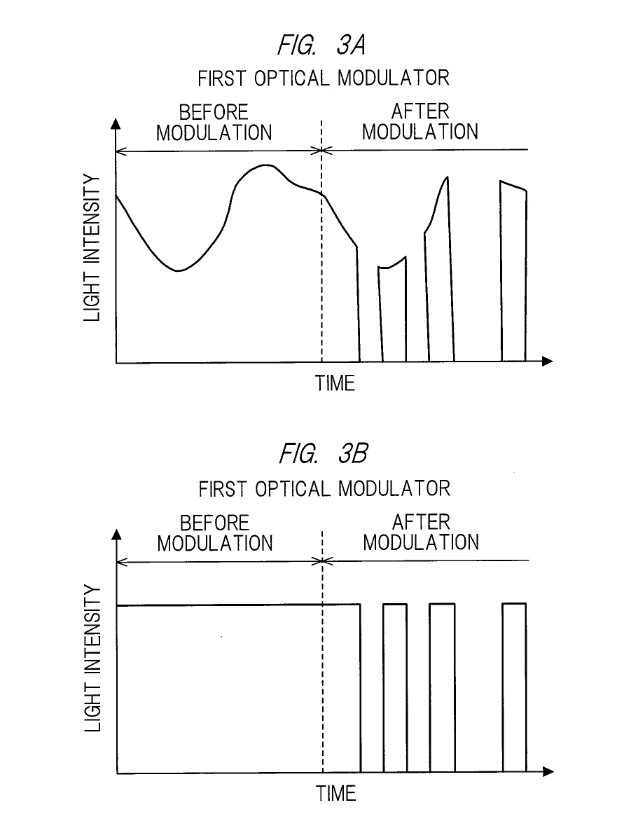

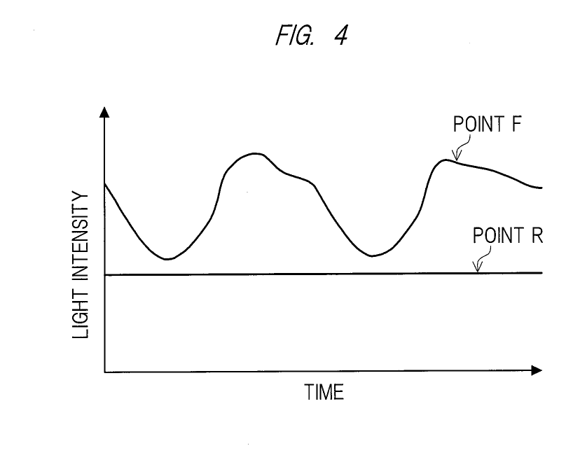

The configuration of the light source according to the first embodiment will be described with reference to FIGS. 2A, 2B, 3A, 3B and FIG. 4. FIGS. 2A and 2B are a plan view and a side view schematically illustrating the configuration of the light source according to the first embodiment. FIGS. 3A and 3B are a graphical representation schematically illustrating a light intensity of laser light in case where the second optical modulator does not manipulate a phase, and a graphical representation schematically illustrating the light intensity of the laser light in case where the second optical modulator manipulates the phase, and illustrate the light intensity of the laser light before and after the first optical modulator performs multi-valued modulation. FIG. 4 is a graphical representation schematically illustrating the light intensity of the laser light before and after the second optical modulator manipulates the phase.

As illustrated in FIGS. 2A and 2B, a light source LS1 is composed of a semiconductor laser LA, a semiconductor laser driver LD, a lens LE, a prism mirror PM, an optical coupling element OC (which is an element which couples beams of light and is also referred to simply as a coupler or an optical coupler), an optical waveguide OW (which includes first optical waveguide OW1 and a second optical waveguide OW2), a light receiving element (which is also referred to as a monitor element) OR, and a second optical modulator OM.

The optical coupling element OC, the optical waveguide OW (including the first optical waveguide OW1 and the second optical waveguide OW2), the light receiving element OR and the second optical modulator OM among these components are formed on a principal surface of a semiconductor substrate SUB made of single crystal silicone (Si) with an insulation layer (also referred to as a BOX layer or a lower clad layer) CLU interposed therebetween. That is, the optical coupling element OC, the optical waveguide OW (including the first optical waveguide OW1 and the second optical waveguide OW2), the light receiving element OR and the second optical modulator OM are formed on one semiconductor chip.

The light receiving element OR is a sensor element which senses whether light is strong or weak. The light receiving element OR is, for example, a photodiode, and is made of a semiconductor such as germanium (Ge) or indium phosphide (InP) having a band gap narrower than an oscillation band gap of the semiconductor laser LA.

Further, the semiconductor laser LA and the semiconductor laser driver LD are formed on different semiconductor chips or the same semiconductor chip, and the embodiment is not limited to these.

The semiconductor laser LA is driven by the semiconductor laser driver LD, and emits light. The laser light emitted from a front surface of the semiconductor laser LA enters the optical coupling element OC via the lens LE and the prism mirror PM, and then propagates in the optical waveguide OW.

The optical waveguide OW in which the laser light emitted from the front surface of the semiconductor laser LA propagates is branched into two; the first optical waveguide OW1 as one of the two extends to an outside of the light source LS1 and connects to the first optical modulator P1; and the second optical waveguide OW2 as the other does not extend to the outside of the light source LS1 and has an end provided with the light receiving element OR which receives part of beams of the laser light. If a light intensity of the laser light having entered the optical waveguide OW is 100 mW, the light intensity of the laser light propagating to the first optical waveguide OW1 is, for example, approximately 99 mW, the light intensity of the laser light propagating to the second optical waveguide OW2 is, for example, approximately 1 mW, and the light amount of most of the laser light having entered the optical waveguide OW propagates to the first optical waveguide OW1.

The optical waveguide OW, the first optical waveguide OW1 and the second optical waveguide OW2 are composed of a semiconductor layer made of, for example, silicone (Si), and the semiconductor layer is formed on the insulation layer CLU. The thickness of the semiconductor layer is, for example, approximately 0.1 to 0.4 μm. The insulation layer CLU has the thickness of, for example, approximately 2 to 3 μm and is formed relatively thick. Consequently, the laser light propagating in the optical waveguide OW, the first optical waveguide OW1 and the second optical waveguide OW2 does not leak to the semiconductor substrate SUB.

The first optical modulator P1 manipulates the phase of the laser light having entered the first optical waveguide OW1 branched from the optical waveguide OW, changes an optical signal state, and associates data transmitted as an electrical signal from an outside with a phase state of the laser light. As described above, the semiconductor device SM outputs an optical signal modulated by the first optical modulator P1 to the outside via the optical coupler P2 such as a grating coupler or a spot size converter (see FIG. 1). The first optical modulator P1 is formed on the principal surface of the semiconductor substrate SUB with the insulation layer CLU interposed therebetween similarly to the optical coupling element OC, the optical waveguide OW, the light receiving element OR and the second optical modulator OM which compose the light source LS1.

However, when laser light is reflected by a reflection surface on an optical path as illustrated in FIG. 3A, returning light fluctuates the light intensity of the laser light. When the laser light having this fluctuating light intensity enters the first optical modulator P1, even if the first optical modulator P1 manipulates the phase, the light intensity of the laser light significantly fluctuates and a fixed light intensity cannot be obtained. In this regard, the word “fixed” does not mean complete fixedness and means substantial fixedness or near fixedness when variations are taken into account.

Hence, in the first embodiment, the light receiving element OR first receives the laser light having entered the second optical waveguide OW2 branched from the optical waveguide OW, and monitors a fluctuation of the light intensity of this laser light. Further, the light receiving element OR converts the monitored fluctuation of the light intensity into an electrical signal and transmits the electrical signal to the second optical modulator OM provided to the first optical waveguide OW1 between the optical coupling element OC and the first optical modulator P1, and the second optical modulator OM performs feedforward modulation on the laser light propagating in the first optical waveguide OW1 at a reverse phase to manipulate the light intensity of the laser light. That is, the light receiving element OR monitors the state of the light intensity of the laser light propagating in the second optical waveguide OW2 at all times, and the second optical modulator OM reflects this state of the light intensity of the laser light in the light intensity of the laser light propagating in the first optical waveguide OW1.

Thus, as illustrated in FIG. 4, before the laser light enters the second optical modulator OM (a point F illustrated in FIG. 2A), even if the light intensity of the laser light significantly fluctuates, the second optical modulator OM manipulates the light intensity of the laser light. Consequently, after the laser light is emitted from the second optical modulator OM (a point R illustrated in FIG. 2A), it is possible to adjust the light intensity of the laser light to the fixed light intensity.

Hence, as illustrated in FIG. 3B, the second optical modulator OM manipulates the light intensity of the laser light propagating in the first optical waveguide OW1 before the first optical modulator P1 manipulates the phase, so that it is possible to obtain a fixed light intensity. The first optical modulator P1 manipulates the phase of this laser light having the fixed light intensity, so that the light intensity of the laser light emitted from the first optical modulator P1 does not fluctuate, and the fixed light intensity can be obtained.

Further, the light receiving element OR feeds forward the obtained fluctuation of the light intensity of the laser light directly to the first optical waveguide OW1, so that it is possible to remarkably shorten an adjustment time compared to adjustment of the light intensity of the laser light fed back via the semiconductor laser driver LD described above (see FIGS. 10A and 10B). Consequently, it is possible to precisely correct the light intensity of the laser light.

Thus, according to the first embodiment, the laser light having the fixed light intensity can enter the first optical modulator P1, so that the light intensity of the laser light emitted from the first optical modulator P1 does not fluctuate, and the semiconductor device including a built-in silicone photonics device can improve communication quality.

### Modified Example of First Embodiment

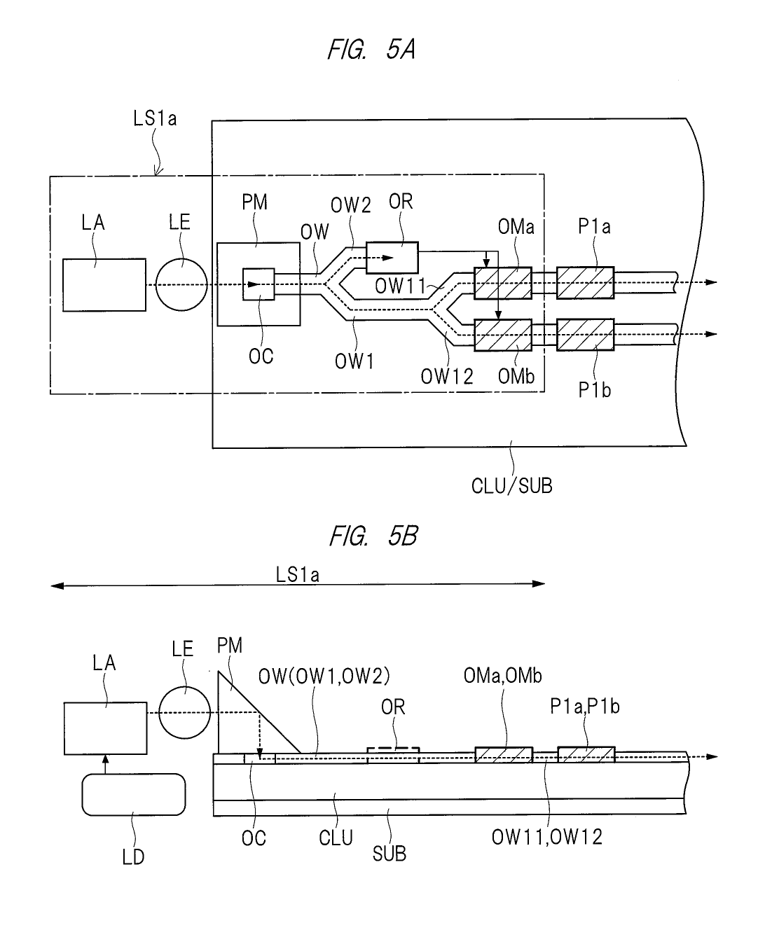

A configuration of a light source according to a modified example of the first embodiment will be described with reference to FIGS. 5A and 5B. FIGS. 5A and 5B are a plan view and a side view schematically illustrating the configuration of the light source according to the modified example of the first embodiment, respectively.

A case where there is one optical modulator which converts data transmitted as an electrical signal into an optical signal has been exemplified in the above first embodiment (see FIGS. 2A and 2B). However, the light source according to the first embodiment can support two or more optical modulators. FIGS. 5A and 5B illustrate the light source according to the modified example of the first embodiment applied to two optical modulators which convert data transmitted as an electrical signal into an optical signal.

The optical waveguide OW of the light source LS1 illustrated in FIGS. 2A and 2B is branched into two; the first optical waveguide OW1 as one of the two extends to an outside of the light source LS1 and connects to the first optical modulator P1; and the second optical waveguide OW2 as the other does not extend to the outside of the light source LS1 and has an end provided with the light receiving element OR which receives part of beams of laser light.

The first optical waveguide OW1 of a light source LS1aaccording to the modified example of the first embodiment extending to an outside of the light source LS1a is further branched into a plurality of waveguides.

As illustrated in FIGS. 5A and 5B, the first optical waveguide OW1 is branched into two of a first branched optical waveguide OW11 and a second branched optical waveguide OW12, the first branched optical waveguide OW11 connects to a first optical modulator P1a, and the second branched optical waveguide OW12 connects to a third optical modulator P1b. In this regard, FIGS. 5A and 5B illustrate examples where the first optical waveguide OW1 is branched into two of the first branched optical waveguide OW11 and the second branched optical waveguide OW12. However, the number of branches is not limited to this, and the first optical waveguide OW1 may be branched into three or more waveguides.

The first branched optical waveguide OW11 connects to the first optical modulator P1a which converts data transmitted as an electrical signal into an optical signal, and a second optical modulator OMa which manipulates a light intensity of laser light is provided between an optical coupling element OC and the first optical modulator P1a. The light receiving element OR monitors a state of the light intensity of the laser light propagating in the second optical waveguide OW2 at all times, and the second optical modulator OMa reflects this state of the light intensity of the laser light in the light intensity of the laser light propagating in the first branched optical waveguide OW11.

Hence, before the first optical modulator P1a manipulates the phase of the light intensity of the laser light propagating in the first branched optical waveguide OW11, the second optical modulator OMa manipulates the light intensity, so that a fixed light intensity can be obtained. Consequently, the first optical modulator P1a manipulates the phase of this laser light having the fixed light intensity, so that the light intensity of the laser light emitted from the first optical modulator P1a does not fluctuate, either, and the fixed light intensity can be obtained.

Similarly, the second branched optical waveguide OW12 connects to the third optical modulator P1b which converts the data transmitted as the electrical signal into the optical signal, and a fourth optical modulator OMb which manipulates the light intensity of the laser light is provided between the optical coupling element OC and the third optical modulator P1b. The light receiving element OR always monitors a state of the light intensity of the laser light propagating in the second optical waveguide OW2, and the fourth optical modulator OMb reflects this state of the light intensity of the laser light in the light intensity of the laser light propagating in the second branched optical waveguide OW12.

Hence, before the third optical modulator P1b manipulates the phase of the light intensity of the laser light propagating in the second branched optical waveguide OW12, the fourth optical modulator OMb manipulates the light intensity, so that a fixed light intensity can be obtained. Consequently, the third optical modulator P1b manipulates the phase of the laser light having the fixed light intensity, so that the light intensity of the laser light emitted from the third optical modulator P1b does not fluctuate, either, and a fixed light intensity can be obtained.

Consequently, according to the modified example of the first embodiment, even when there are the plural optical modulators which converts the data transmitted as the electrical signal into the optical signal, the laser light having the fixed light intensity can enter the respective optical modulators (the first and third optical modulators P1a and P1b), so that it is possible to prevent the light intensities of beams of the laser light emitted from the respective optical modulators (first and third optical modulators P1a and P1b) from fluctuating.

### Second Embodiment

<<Configuration of Light Source>>

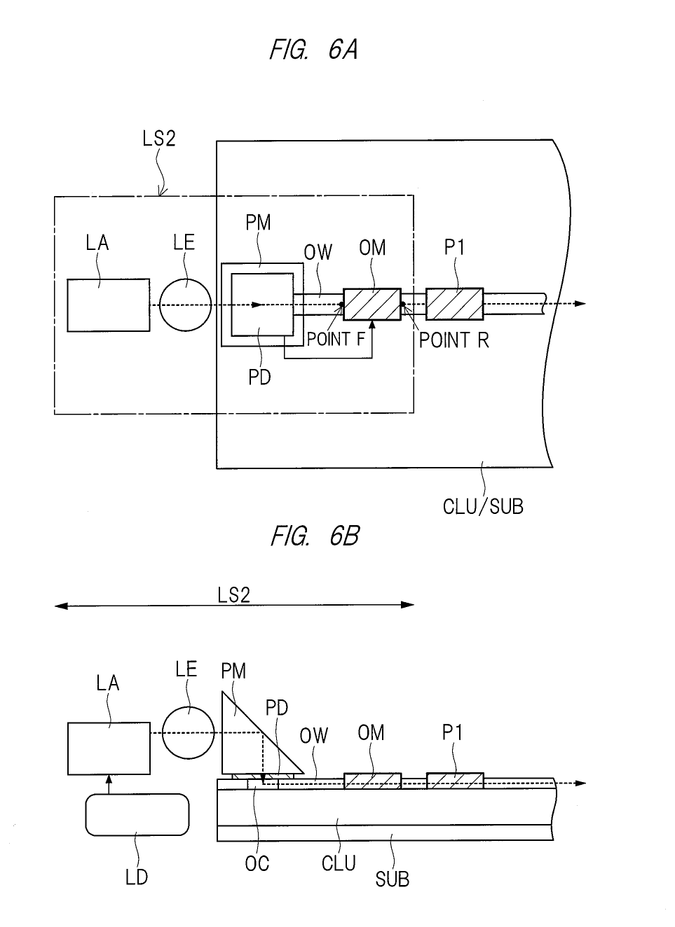

A configuration of a light source according to a second embodiment will be described with reference to FIGS. 6A and 6B. FIGS. 6A and 6B area plan view and a side view schematically illustrating the configuration of the light source according to the second embodiment, respectively.

As illustrated in FIGS. 6A and 6B, a light source LS2 is composed of a semiconductor laser LA, a semiconductor laser driver LD, a lens LE, a prism mirror PM, a light receiving element (also referred to as a monitor element) PD, an optical coupling element OC, an optical waveguide OW, and a second optical modulator OM.

The light receiving element PD, the optical coupling element OC, the optical waveguide OW and the second optical modulator OM among these components are formed on a principal surface of a semiconductor substrate SUB made of single crystal silicone (Si) with an insulation layer CLU interposed therebetween. That is, the light receiving element PD, the optical coupling element OC, the optical waveguide OW and the second optical modulator OM are formed on one semiconductor chip.

The light receiving element PD is a sensor element which senses whether light is strong or weak. The light receiving element PD is, for example, a photodiode, and is made of a semiconductor such as germanium (Ge) or indium phosphide (InP) having a band gap narrower than an oscillation band gap of the semiconductor laser LA.

Further, the semiconductor laser LA and the semiconductor laser driver LD are formed on different semiconductor chips or the same semiconductor chip, and the embodiment is not limited to these.

The semiconductor laser LA is driven by the semiconductor laser driver LD, and emits light. The laser light emitted from a front surface of the semiconductor laser LA enters the optical coupling element OC via the lens LE, the prism mirror PM and the light receiving element PD, and then propagates in the optical waveguide OW.

The optical waveguide OW in which the laser light emitted from the front surface of the semiconductor laser LA propagates is composed of a semiconductor layer made of, for example, silicone (Si), and this semiconductor layer is formed on the insulation layer CLU. The thickness of the semiconductor layer is, for example, approximately 0.1 to 0.4 μm. The insulation layer CLU has a thickness of, for example, approximately 2 to 3 μm and is formed relatively thick. Consequently, the laser light propagating in the optical waveguide OW does not leak to the semiconductor substrate SUB.

A first optical modulator P1 manipulates the phase of the laser light having entered the optical waveguide OW, changes an optical signal state, and associates data transmitted as an electrical signal from an outside with a phase state of the laser light. As described above, the semiconductor device SM outputs the optical signal modulated by the first optical modulator P1 to the outside via the optical coupler P2 such as a grating coupler or a spot size converter (see FIG. 1). The first optical modulator P1 is formed on the principal surface of the semiconductor substrate SUB with the insulation layer CLU interposed therebetween similarly to the light receiving element PD, the optical coupling element OC, the optical waveguide OW and the second optical modulator OM which compose the light source LS2.

However, when the laser light is reflected by the reflection surface on the optical path as illustrated in FIG. 3A, the returning light fluctuates the light intensity of the laser light. When the laser light having this fluctuating light intensity enters the first optical modulator P1, even if the first optical modulator P1 manipulates the phase, the light intensity of the laser light significantly fluctuates, and the fixed light intensity cannot be obtained.

Hence, in the second embodiment, the light receiving element PD first receives the laser light emitted from the semiconductor laser LA before the laser light enters the optical coupling element OC, and monitors a fluctuation of the light intensity of this laser light. A light amount absorbed by the light receiving element PD is directly proportional to an output of the semiconductor laser LA. Further, the light receiving element PD converts the fluctuation of the monitored light intensity into an electrical signal and transmits the electrical signal to the second optical modulator OM provided to the optical waveguide OW between the optical coupling element OC and the first optical modulator P1. The second optical modulator OM performs feedforward modulation on the laser light propagating in the optical waveguide OW at a reverse phase to manipulate the light intensity of the laser light. That is, the light receiving element PD monitors the state of the light intensity of the laser light entering the optical coupling element OC at all times. The second optical modulator OM reflects this state of the light intensity of the laser light in the light intensity of the laser light propagating in the optical waveguide OW.

Thus, as illustrated in FIG. 4, before the laser light enters the second optical modulator OM (the point F illustrated in FIG. 6A), even if the light intensity of the laser light significantly fluctuates, the second optical modulator OM manipulates the light intensity of the laser light. Consequently, after the laser light is emitted from the second optical modulator OM (the point R illustrated in FIG. 6A), it is possible to adjust the light intensity of the laser light to the fixed light intensity.

Hence, as illustrated in FIG. 3B, the second optical modulator OM manipulates the light intensity of the laser light propagating in the optical waveguide OW before the first optical modulator P1 manipulates the phase, so that it is possible to obtain the fixed light intensity. The first optical modulator P1 manipulates the phase of the laser light having this fixed light intensity, so that the light intensity of the laser light emitted from the first optical modulator P1 does not fluctuate, either, and the fixed light intensity can be obtained.

Further, the light receiving element PD feeds forward the obtained fluctuation of the light intensity of the laser light directly to the optical waveguide OW, so that it is possible to remarkably shorten an adjustment time compared to adjustment of the light intensity of the laser light fed back via the semiconductor laser driver LD described above (see FIGS. 10A and 10B). Consequently, it is possible to precisely correct the light intensity of the laser light.

Thus, according to the second embodiment, the laser light having the fixed light intensity can enter the first optical modulator P1 similarly to the above-described first embodiment, so that the light intensity of the laser light emitted from the first optical modulator P1 does not fluctuate, and a semiconductor device including a built-in silicone photonics device can improve communication quality.

### Third Embodiment

<<Configuration of Light Source>>

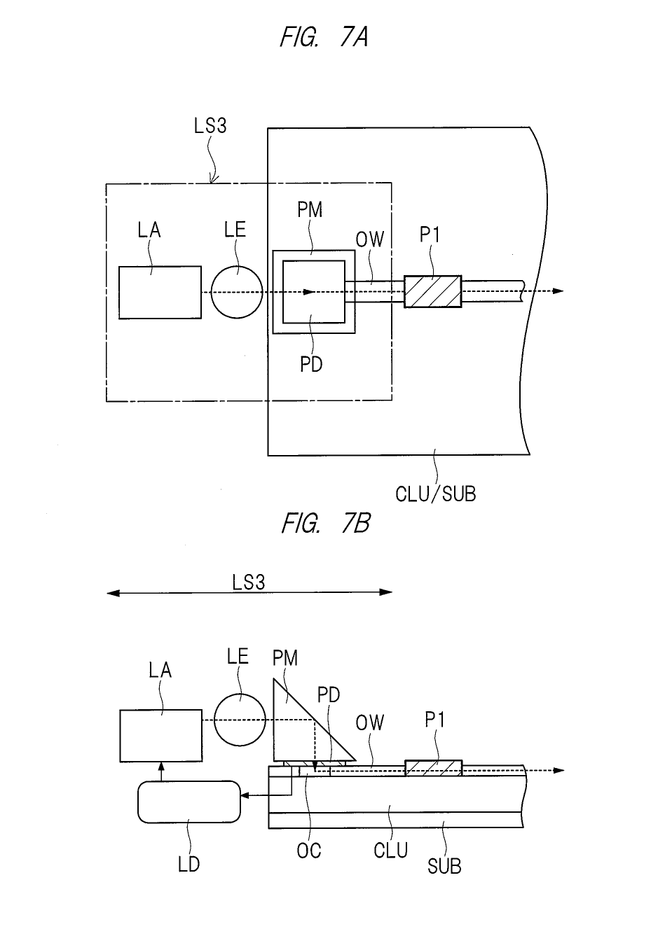

A configuration of a light source according to a third embodiment will be described with reference to FIGS. 7A and 7B. FIGS. 7A and 7B area plan view and a side view schematically illustrating the configuration of the light source according to the third embodiment, respectively.

As illustrated in FIGS. 7A and 7B, a light source LS3 is composed of a semiconductor laser LA, a semiconductor laser driver LD, a lens LE, a prism mirror PM, a light receiving element PD, an optical coupling element OC, and an optical waveguide OW.

The light receiving element PD, the optical coupling element OC and the optical waveguide OW among these components are formed on a principal surface of a semiconductor substrate SUB made of single crystal silicone (Si) with an insulation layer CLU interposed therebetween. That is, the light receiving element PD, the optical coupling element OC and the optical waveguide OW are formed on one semiconductor chip.

Further, the semiconductor laser LA and the semiconductor laser driver LD are formed on different semiconductor chips or the same semiconductor chip, and the embodiment is not limited to these.

The semiconductor laser LA is driven by the semiconductor laser driver LD, and emits light. The laser light emitted from a front surface of the semiconductor laser LA enters the optical coupling element OC via the lens LE, the prism mirror PM and the light receiving element PD, and then propagates in the optical waveguide OW.

The optical waveguide OW in which the laser light emitted from the front surface of the semiconductor laser LA propagates is composed of a semiconductor layer made of, for example, silicone (Si), and this semiconductor layer is formed on the insulation layer CLU. The thickness of the semiconductor layer is, for example, approximately 0.1 to 0.4 μm. The insulation layer CLU has a thickness of, for example, approximately 2 to 3 μm and is formed relatively thick. Consequently, the laser light propagating in the optical waveguide OW does not leak to the semiconductor substrate SUB.

A first optical modulator P1 manipulates the phase of the laser light having entered the optical waveguide OW, changes an optical signal state, and associates data transmitted as an electrical signal from an outside with a phase state of the laser light. As described above, a semiconductor device SM outputs an optical signal modulated by the first optical modulator P1 to the outside via an optical coupler P2 such as a grating coupler or a spot size converter (see FIG. 1). The first optical modulator P1 is formed on the principal surface of the semiconductor substrate SUB with the insulation layer CLU interposed therebetween similarly to the light receiving element PD, the optical coupling element OC, and the optical waveguide OW which compose the light source LS3.

However, when the laser light is reflected by the reflection surface on the optical path as illustrated in FIG. 3A, the returning light fluctuates the light intensity of the laser light. When the laser light having this fluctuating light intensity enters the first optical modulator P1, even if the first optical modulator P1 manipulates the phase, the light intensity of the laser light significantly fluctuates, and the fixed light intensity cannot be obtained.

Hence, in the third embodiment, the light receiving element PD first receives the laser light emitted from the semiconductor laser LA before the laser light enters the optical coupling element OC, and monitors a fluctuation of the light intensity of this laser light. A light amount absorbed by the light receiving element PD is directly proportional to an output of the semiconductor laser LA. Further, the light receiving element PD converts the fluctuation of the monitored light intensity into an electrical signal, feeds back the electrical signal to the semiconductor laser driver LD, and controls power of the electrical signal to adjust the light intensity of the laser light emitted from the semiconductor laser LA. That is, the light receiving element PD monitors the state of the light intensity of the laser light entering the optical coupling element OC at all times, and the semiconductor laser driver LD reflects this state of the light intensity of the laser light in the light intensity of the laser light emitted from the semiconductor laser LA.

Thus, the laser light whose phase is not yet manipulated by the first optical modulator P1 can have the fixed light intensity. The first optical modulator P1 manipulates the phase of this laser light having the fixed light intensity, so that the light intensity of the laser light emitted from the first optical modulator P1 does not fluctuate, either, and the fixed light intensity can be obtained.

In this regard, in the third embodiment, the interposed semiconductor laser driver LD adjusts the light intensity of the laser light emitted from the semiconductor laser LA. Therefore, a time delay caused by feedback makes it difficult to correct the light intensity of the laser light with high precision compared to the light source LS1 according to the first embodiment and the light source LS2 according to the second embodiment.

However, it is possible to shorten the time delay caused by the feedback compared to the light source LSO (FIGS. 10A and 10B) which adjusts the light intensity of the laser light via the light receiving element OR and the semiconductor laser driver LD as described above.

Thus, according to the third embodiment, the light intensity of the laser light does not fluctuate, and the semiconductor device including a built-in silicone photonics device can improve communication quality.

### Fourth Embodiment

<<Configuration of Light Source>>

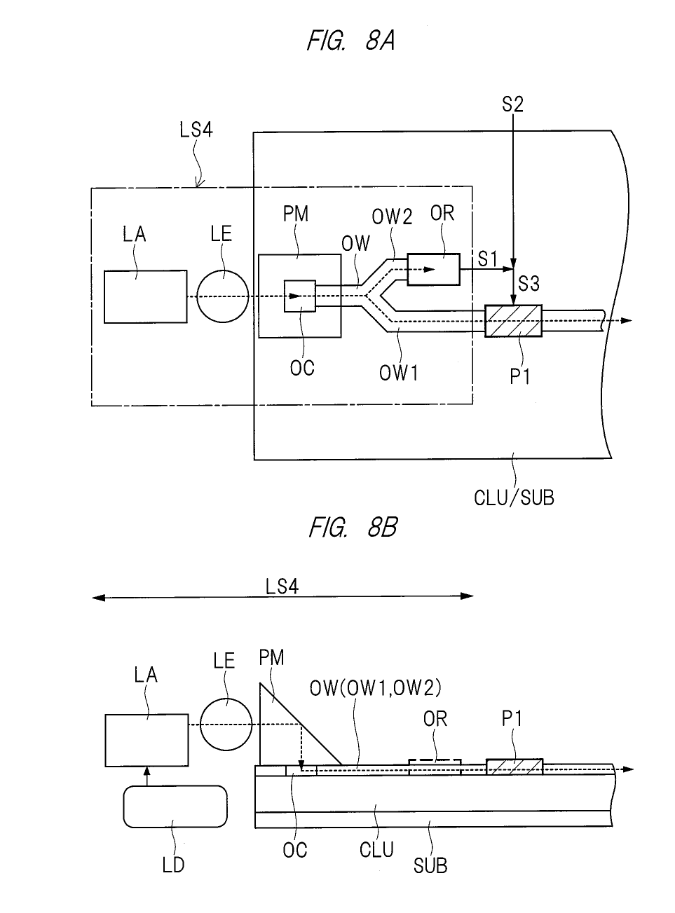

A configuration of a light source according to a fourth embodiment will be described with reference to FIGS. 8A and 8B. FIGS. 8A and 8B area plan view and a side view schematically illustrating the configuration of the light source according to the fourth embodiment, respectively.

As illustrated in FIGS. 8A and 8B, a light source LS4 is composed of a semiconductor laser LA, a semiconductor laser driver LD, a lens LE, a prism mirror PM, an optical coupling element OC, an optical waveguide OW (a first optical waveguide OW1 and a second optical waveguide OW2), and a light receiving element OR. That is, the light source LS4 according to the fourth embodiment differs from the light source LS1 according to the first embodiment in that the light source LS4 does not include the second optical modulator OM.

The optical coupling element OC, the optical waveguide OW (including the first optical waveguide OW1 and the second optical waveguide OW2) and the light receiving element OR among these components are formed on a principal surface of a semiconductor substrate SUB made of single crystal silicone (Si) with an insulation layer CLU interposed therebetween. That is, the optical coupling element OC, the optical waveguide OW (including the first optical waveguide OW1 and the second optical waveguide OW2) and the light receiving element OR are formed on one semiconductor chip.

The semiconductor laser LA is driven by the semiconductor laser driver LD, and emits light. The laser light emitted from a front surface of the semiconductor laser LA enters the optical coupling element OC via the lens LE and the prism mirror PM, and then propagates in the optical waveguide OW.

Similarly to the above-described first embodiment, the optical waveguide OW in which the laser light emitted from the front surface of the semiconductor laser LA propagates is branched into two; the first optical waveguide OW1 as one of the two extends to an outside of the light source LS4 and connects to a first optical modulator P1; and the second optical waveguide OW2 as the other does not extend to the outside of the light source LS4 and has an end provided with the light receiving element OR which receives part of beams of the laser light.

The optical waveguide OW, the first optical waveguide OW1 and the second optical waveguide OW2 are composed of a semiconductor layer made of, for example, silicone (Si), and the semiconductor layer is formed on the insulation layer CLU. The thickness of the semiconductor layer is, for example, approximately 0.1 to 0.4 μm. The insulation layer CLU has a thickness of, for example, approximately 2 to 3 μm and is formed relatively thick. Consequently, the laser light propagating in the optical waveguide OW, the first optical waveguide OW1 and the second optical waveguide OW2 does not leak to the semiconductor substrate SUB.

The first optical modulator P1 manipulates the phase of the laser light having entered the first optical waveguide OW1 branched from the optical waveguide OW, changes an optical signal state, and associates data transmitted as an electrical signal from an outside with a phase state of the laser light. As described above, the semiconductor device SM outputs the optical signal modulated by the first optical modulator P1 to the outside via the optical coupler P2 such as a grating coupler or a spot size converter (see FIG. 1). The first optical modulator P1 is formed on the principal surface of the semiconductor substrate SUB with the insulation layer CLU interposed therebetween similarly to the optical coupling element OC, the optical waveguide OW, and the light receiving element OR which compose the light source LS4.

However, when the laser light is reflected by the reflection surface on the optical path as illustrated in FIG. 3A, the returning light fluctuates the light intensity of the laser light. When the laser light having this fluctuating light intensity enters the first optical modulator P1, even if the first optical modulator P1 manipulates the phase, the light intensity of the laser light significantly fluctuates, and the fixed light intensity cannot be obtained.

Hence, in the fourth embodiment, the light receiving element OR first receives the laser light having entered the second optical waveguide OW2 branched from the optical waveguide OW, and monitors a fluctuation of the light intensity of this laser light. Further, the light receiving element OR converts the monitored fluctuation (variation or noise) of the light intensity into a first electrical signal S1 of a reverse phase, and superimposes the first electrical signal S1 on a second electrical signal S2 transmitted from an outside such as the silicone electronic circuit C2 (see FIG. 1). Furthermore, the light receiving element OR transmits to the first optical modulator P1 a third electrical signal S3 obtained by superimposing the first electrical signal S1 on the second electrical signal S2. The first optical modulator P1 converts the electrical signal into an optical signal, and simultaneously performs feed-forward modulation on the light intensity of the laser light entering the first optical modulator P1.

That is, the light receiving element OR transmits to the first optical modulator P1 the third electrical signal S3 obtained by superimposing, on the second electrical signal S2 transmitted from the outside, a signal (first electrical signal) whose light intensity of the laser light propagating in the first optical waveguide OW1 has the reverse phase. Therefore, even when the light intensity of the laser light entering the first optical modulator P1 fluctuates, it is possible to manipulate the light intensity of the laser light according to the third electrical signal S3.

Consequently, even when the light intensity of the laser light significantly fluctuates before the laser light enters the first optical modulator P1, the first optical modulator P1 can manipulate the phase and adjust the laser light of the light intensity to the fixed light intensity. Therefore, the light intensity of the laser light emitted from the first optical modulator P1 does not fluctuate, and the fixed light intensity can be obtained.

Further, the light receiving element OR feeds forward the obtained fluctuation of the light intensity of the laser light directly to the first optical waveguide OW1, so that it is possible to remarkably shorten an adjustment time compared to adjustment of the light intensity of the laser light fed back via the semiconductor laser driver LD described above (see FIGS. 10A and 10B). Consequently, it is possible to precisely correct the light intensity of the laser light.

Thus, according to the fourth embodiment, the light intensity of the laser light emitted from the first optical modulator P1 does not fluctuate, and the semiconductor device including a built-in silicone photonics device can improve communication quality. Further, in addition to this, the number of optical modulators decreases compared to the first embodiment, so that it is possible to miniaturize a semiconductor device.

### Modified Example of Fourth Embodiment

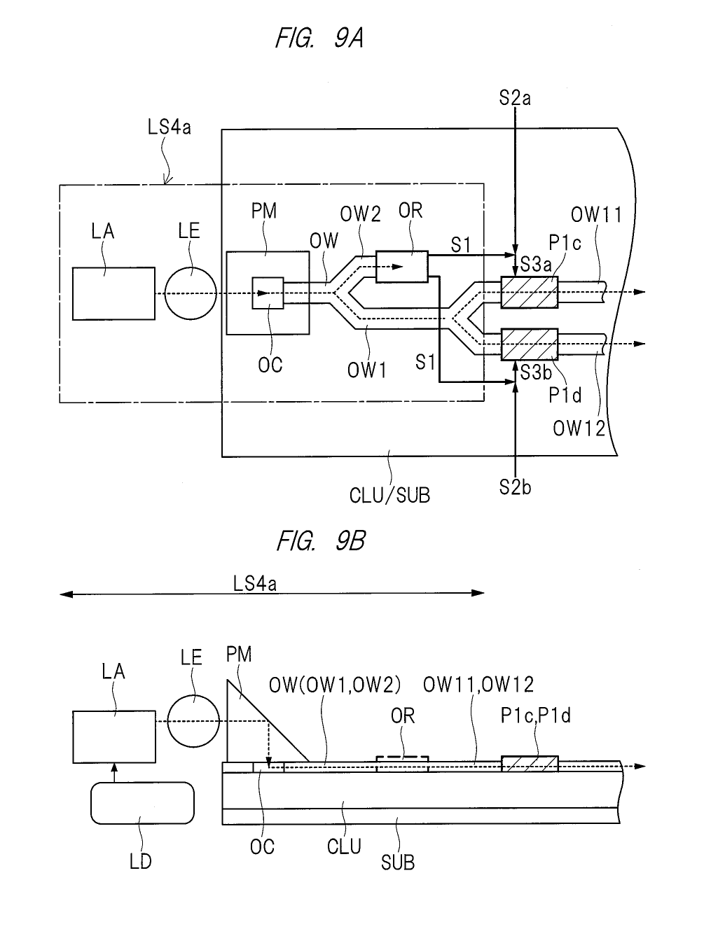

A configuration of a light source according to a modified example of the fourth embodiment will be described with reference to FIGS. 9A and 9B. FIGS. 9A and 9B are a plan view and a side view schematically illustrating the configuration of the light source according to the modified example of the fourth embodiment, respectively.

A case where there is one optical modulator which converts the data transmitted as the electrical signal into the optical signal has been exemplified in the above fourth embodiment (see FIGS. 8A and 8B). However, the light source according to the fourth embodiment can support two or more optical modulators. FIGS. 9A and 9B illustrate a light source according the modified example of to the fourth embodiment applied to two optical modulators which convert data transmitted as an electrical signal into an optical signal.

The optical waveguide OW of the light source LS4 illustrated in FIGS. 8A and 8B is branched into two; the first optical waveguide OW1 as one of the two extends to the outside of the light source LS4 and connects to the first optical modulator P1; and the second optical waveguide OW2 as the other does not extend to the outside of the light source LS4 and has the end provided with the light receiving element OR which receives part of beams of the laser light.

The first optical waveguide OW1 of a light source LS4a according to the modified example of the fourth embodiment extending to the outside of the light source LS4a is further branched into a plurality of waveguides.

As illustrated in FIGS. 9A and 9B, the first optical waveguide OW1 is branched into two of a first branched optical waveguide OW11 and a second branched optical waveguide OW12. The first branched optical waveguide OW11 connects to a first optical modulator P1c, and the second branched optical waveguide OW12 connects to a second optical modulator P1d. In this regard, FIGS. 9A and 9B illustrate examples where the first optical waveguide OW1 is branched into two of the first branched optical waveguide OW11 and the second branched optical waveguide OW12. However, the number of branches is not limited to this, and the first optical waveguide OW1 maybe branched into three or more waveguides.

The first branched optical waveguide OW11 connects to the first optical modulator P1c which converts data transmitted as an electrical signal into an optical signal. The light receiving element OR monitors a state of the light intensity of the laser light propagating in the second optical waveguide OW2 at all times, and the state of the light intensity of the laser light becomes a first electrical signal S1 of a reverse phase signal. The light receiving element OR superimposes the first electrical signal S1 on the second electrical signal S2a transmitted from the outside, converts the second electrical signal S2a into a third electrical signal S3a, and transmits, to the first optical modulator P1c, the third electrical signal S3a reflecting the state of the light intensity of the laser light.

Accordingly, the light receiving element OR superimposes, on the second electrical signal S2a, the state of the light intensity of the laser light propagating in the first branched optical waveguide OW11 as the reverse phase signal (first electrical signal S1). Therefore, even when the light intensity of the laser light entering the first optical modulator P1c fluctuates, it is possible to manipulate the light intensity of this laser light according to the third electrical signal S3a. Consequently, the first optical modulator P1c can manipulate the phase and adjust the light intensity of the laser light to the fixed light intensity, so that the light intensity of the laser light emitted from the first optical modulator P1c does not fluctuate, and the fixed light intensity can be obtained.

Similarly, the second branched optical waveguide OW12 connects to the second optical modulator P1d which converts the data transmitted as the electrical signal into an optical signal. The light receiving element OR always monitors the state of the light intensity of the laser light propagating in the second optical waveguide OW2, and the state of the light intensity becomes the first electrical signal S1 of the reverse phase signal. The light receiving element OR superimposes the first electrical signal S1 on a second electrical signal S2b transmitted from the outside, converts the second electrical signal S2b into a third electrical signal S3b, and transmits, to the second optical modulator P1d, the third electrical signal S3b reflecting the state of the light intensity of the laser light.

Accordingly, the light receiving element OR superimposes, on the second electrical signal S2b, the state of the light intensity of the laser light propagating in the second branched optical waveguide OW12 as the reverse phase signal (first electrical signal S1). Therefore, even when the light intensity of the laser light entering the second optical modulator P1d fluctuates, it is possible to manipulate the light intensity of the laser light according to the third electrical signal S3b. Consequently, the second optical modulator P1d can manipulate the phase, and simultaneously adjust the light intensity of the laser light to the fixed light intensity, so that the light intensity of the laser light emitted from the second optical modulator P1d does not fluctuate, and the fixed light intensity can be obtained.

Thus, according to the modified example of the fourth embodiment, even when there are the plural optical modulators which converts the data transmitted as the electrical signal into the optical signal, the laser light having the fixed light intensity can enter the respective optical modulators (the first and second optical modulators P1c and P1d), so that it is possible to prevent the light intensities of beams of the laser light emitted from the respective optical modulators (the first and second optical modulators P1c and P1d) from fluctuating.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, the prism mirror has been used as a wavelength selecting mirror in the above-described embodiments. However, the present invention is not limited to this, and a wavelength selecting mirror for which a semiconductor layer formed on a principal surface of a semiconductor substrate with an insulation layer interposed therebetween is used may be formed. In this case, it is possible to form, for example, a semiconductor laser, a semiconductor laser driver, a wavelength selecting mirror, an optical modulator and optical waveguides on one semiconductor chip. Further, it is also possible to form, for example, a semiconductor laser on one semiconductor chip, and, for example, a semiconductor laser driver, a wavelength selecting mirror, an optical modulator and an optical waveguide on the other one semiconductor chip.

What is claimed is:

1. A semiconductor device comprising:
a semiconductor laser;
a first optical waveguide in which laser light emitted from the semiconductor laser propagates;
a first optical modulator which modulates the laser light propagating in the first optical waveguide, based on first data transmitted as a first electrical signal, and converts the first electrical signal into an optical signal; and
a second optical modulator which is disposed on the first optical waveguide between the semiconductor laser and the first optical modulator, and adjusts a light intensity of the laser light entering the first optical modulator.

2. The semiconductor device according to claim 1, further comprising:
a second optical waveguide which is branched from the first optical waveguide between the semiconductor laser and the second optical modulator; and
a monitor element which is connected to an end of the second optical waveguide and converts part of beams of the received laser light into a second electrical signal,
wherein the second optical modulator adjusts the light intensity of the laser light entering the first optical modulator, based on second data transmitted as the second electrical signal.

3. The semiconductor device according to claim 2, wherein the laser light entering the first optical modulator is subjected to feedforward modulation at a reverse phase.

4. The semiconductor device according to claim 2, wherein the monitor element is a photodiode composed of a semiconductor including a band gap narrower than an oscillation band gap of the semiconductor laser.

5. The semiconductor device according to claim 2, wherein the monitor element is a photodiode made of one of germanium and indium phosphide.

6. The semiconductor device according to claim 1, further comprising a monitor element which is disposed between the semiconductor laser and the second optical modulator, and converts the received laser light into the second electrical signal,
wherein a second optical modulator adjusts the light intensity of the laser light entering the first optical modulator, based on second data transmitted as the second electrical signal.

7. The semiconductor device according to claim 6, wherein the laser light entering the first optical modulator is subjected to feedforward modulation at a reverse phase.

8. The semiconductor device according to claim 6, wherein the monitor element is a photodiode composed of a semiconductor including a band gap narrower than an oscillation band gap of the semiconductor laser.

9. The semiconductor device according to claim 6, wherein the monitor element is a photodiode made of one of germanium and indium phosphide.

10. The semiconductor device according to claim 1, wherein the first optical waveguide is formed by a semiconductor layer on a principal surface of a semiconductor substrate made of silicone with an insulation film interposed therebetween.

11. The semiconductor device according to claim 1, wherein the semiconductor laser, the first optical waveguide, the first optical modulator and the second optical modulator are formed on one semiconductor chip.

12. The semiconductor device according to claim 1, wherein a number of the first optical modulator is two or more, and each of the first optical modulators includes the second optical modulator.

13. A semiconductor device comprising:
a semiconductor laser;
a semiconductor laser driver which drives the semiconductor laser;
an optical waveguide in which laser light emitted from the semiconductor laser propagates;
an optical modulator which modulates the laser light propagating in the optical waveguide, based on first data transmitted as a first electrical signal, and converts the first electrical signal into an optical signal; and
a monitor element which is disposed between the semiconductor laser and the optical modulator and converts the received laser light into a second electrical signal,
wherein a light intensity of the laser light emitted from the semiconductor laser is adjusted by controlling the semiconductor laser driver based on second data transmitted as the second electrical signal.

14. The semiconductor device according to claim 13, wherein the monitor element is a photodiode composed of a semiconductor including a band gap narrower than an oscillation band gap of the semiconductor laser.

15. The semiconductor device according to claim 13, wherein the monitor element is a photodiode made of one of germanium and indium phosphide.

16. A semiconductor device comprising:
a semiconductor laser;
a first optical waveguide in which laser light emitted from the semiconductor laser propagates;
an optical modulator which modulates the laser light propagating in the first optical waveguide;
a second optical waveguide which is branched from the first optical waveguide between the semiconductor laser and the optical modulator; and
a monitor element which is connected to an end of the second optical waveguide and converts part of beams of the received laser light into a first electrical signal of a reverse phase,
wherein the first electrical signal is superimposed on a second electrical signal transmitted from an outside, the second electrical signal is converted into a third electrical signal, and the optical modulator adjusts a light intensity of the laser light based on data transmitted as the third electrical signal and converts the third electrical signal into an optical signal.

17. The semiconductor device according to claim 16, wherein the laser light entering the optical modulator is subjected to feedforward modulation at a reverse phase.

18. The semiconductor device according to claim 16, wherein the monitor element is a photodiode composed of a semiconductor including a band gap narrower than an oscillation band gap of the semiconductor laser.

19. The semiconductor device according to claim 16, wherein the monitor element is a photodiode made of one of germanium and indium phosphide.

20. The semiconductor device according to claim 16, wherein a number of the optical modulator is two or more, and the third electrical signal is transmitted to each of the optical modulators.
